(19) United States
(12) Patent Application Publication
(10) Pub. No.: US 2021/0033274 A1
(43) Pub. Date: Feb. 4, 2021

(54) A LIGHTING DEVICE COMPRISING A HOUSING AND A BAG

(71) Applicant: SIGNIFY HOLDING B.V., EINDHOVEN (NL)

(72) Inventors: MARK JOHANNES ANTONIUS VERHOEVEN, MAARHEEZE (NL); VINCENT STEFAN DAVID GIELEN, EINDHOVEN (NL)

(21) Appl. No.: 17/046,151

(22) PCT Filed: Apr. 12, 2019
(86) PCT No.: PCT/EP2019/059410

§ 371 Date: Oct. 8, 2020

(30) Foreign Application Priority Data
Apr. 19, 2018 (EP) 18168114.9

(51) Int. Cl. F21V 31/04; F21V 31/00; F21V 15/01

(52) U.S. Cl. CPC F21V 31/04; F21W 2131/103; F21V 15/012; F21V 31/005

(57) ABSTRACT

It is an object of the invention to provide an improved lighting device, which may compensate a pressure drop occurring. Thereto, the invention provides a lighting device (10) comprising a housing (11) and a bag (15) made of a bag material; wherein the housing (11) comprises a light source (23) and a light exit window (22) for outputting light of the light source (23) to the exterior; wherein the housing (11) has a housing volume (12) filled with air (13) having a housing pressure (14); wherein the bag (15) is gastightly sealed (17) with a bag material, and is filled with a bag fluid (16), and is contained within the housing volume (12); wherein the bag (15) is configured to expand for reducing the housing volume (12) and for thereby compensating a pressure drop in the housing pressure (14) of the air (13).

### FIELD OF THE INVENTION

The invention relates to a lighting device, wherein the lighting device comprises a housing and a bag. The invention further relates to a method of compensating a pressure drop in a lighting device, wherein the lighting device comprises a housing and a bag. The invention further relates to a method of equipping a lighting device with a bag.

### BACKGROUND OF THE INVENTION

A lighting device, such as an outdoor luminaire, may be subject to an instantaneous temperature drop e.g. during operation. For example, an operating outdoor luminaire may experience a temperature drop of its interior volume due to an instantaneous change in weather conditions at its exterior, such as a sudden rainfall. Another example, an operating luminaire may experience a temperature drop of its interior volume due to a scheduled cleaning of its exterior with pressurized water.

In such cases, which occur regularly and/or periodically, the instantaneous temperature drop may cause a sudden pressure drop within the lighting device, i.e. within a housing and/or optical enclosure of the lighting device; because the drop in temperature compresses the fluid within the lighting device and creates a vacuum. Such a (sudden) pressure drop is undesired, because the resulting pressure differential may put a mechanical stress on walls, joints, gaskets and/or seals of the lighting device, which reduces the operability and lifetime of the lighting device. Such pressure differences may therefore result in failing gaskets, joints and/or seals, hence leading to leaks. Such leaks are disadvantageous, because the lighting device may consequently be more prone to ingress of contaminants.

A pressure difference in a lighting device relative to its exterior is commonly counteracted by equipping the lighting device with a breather for equalizing, over time, the pressure at the interior and exterior of the lighting device. However: a clear disadvantage of a breather is that it cannot cope with an instantaneous pressure difference, as for example indicated above, because the flow-rate through the breather is usually limited and hence the breather cannot timely equalize the pressure at the interior of the lighting device with the exterior of the luminaire. As a result, an instantaneous pressure drop occurring within the luminaire (e.g. due to said temperature drop) will suck in undesired contaminants such as water, dust, dirt, insects, or moisture within e.g. the housing of the lighting device; either via the breather itself, because it is disadvantageously open to the exterior, or via leaks in the housing.

The above-mentioned pressure differences, which occur in a lighting device, may alternatively be addressed by a respiratory means acting as a piston or bellow, such as CN102878539. Another example of equalizing pressure is found in US2008314899, wherein a membrane is used for pressure compensation. Such membranes are also known from e.g. CN206724027U. All such means for reducing a pressure difference occurring in a lighting device are nevertheless disadvantageous, because the lighting device requires an additional aperture for accommodating said membranes or respiratory means, wherein the membrane may be in connection with an exterior environment and hence prone to damage or wear. Moreover, as such means require adaptation of the lighting device construction itself, such options are not applicable for upgrading or retrofitting an existing lighting device to cope with the mentioned pressure differences and related undesired ingress.

### SUMMARY OF THE INVENTION

It is an object of the invention to provide an improved lighting device, which at least alleviates the problems and disadvantages mentioned above, e.g. an improved ingress protection and thereby an improved lifetime. Thereto, the invention provides a lighting device comprising a housing and a bag made of a bag material; wherein the housing comprises a light source and a light exit window for outputting light of the light source to the exterior; wherein the housing has a housing volume filled with a housing fluid having a housing pressure; wherein the bag is gastightly sealed, and is filled with a bag fluid, and is contained within the housing volume; wherein the bag is configured to expand for reducing the housing volume and for thereby compensating a pressure drop in the housing pressure of the housing fluid; wherein the bag material comprises a Modulus of Elasticity of at least 0.1 GPa and at most 5 GPa.

The housing fluid may be a gas. Here: The housing fluid is air. Hence, according to the invention, housing fluid and air may be phrased interchangeably throughout the present application.

Such a lighting device comprises a housing. The housing comprises a light source and a light exit window for outputting light of the light source to the exterior. The housing encloses an interior of the lighting device. The housing has a housing volume filled with a housing fluid having a housing pressure. As known in practice, as e.g. indicated in the background section, the housing volume may be prone to pressure differences. The housing fluid may for example experience a sudden pressure drop with respect to an ambient fluid, i.e. e.g. the ambient fluid surrounding the housing of the lighting device. This sudden pressure drop is undesired, because it not only puts mechanical stress on gaskets, seals, joints, and/or walls, but it also allows contaminants such as water, moisture, dust, dirt, insects, etc. to be sucked into the housing via leaks or apertures due to the resulting negative pressure gradient (i.e. pressure inside housing is lower than outside the housing).

The Modulus of Elasticity is a measure for stiffness. Hence, here, stiffness and Modulus of Elasticity may be used interchangeably in phrasing. Hence, the bag material comprises a stiffness of at least 0.1 GPa and at most 5 GPa.

The bag according to the invention reduces the mentioned undesired or disadvantageous consequences of said pressure drop. Namely: The bag is filled with a bag fluid, the bag is made of a bag material, the bag is gastightly sealed with a bag material, and the bag is contained within the housing volume. Hence, the bag may initially not be affected by the occurring pressure drop, as the bag fluid is isolated from the housing fluid. Therefore, the bag may expand whenever the housing volume experiences a (sudden) pressure drop in the housing pressure of its housing fluid. As the bag is contained within the housing volume, the expansion of the bag will reduce the housing volume. A reduction of the housing volume will subsequently result into an increase in of the housing pressure of the housing fluid. Thus, the (sudden) pressure drop in the housing pressure of the housing fluid will be compensated.

The present invention therefore provides an improved lighting device, which is able to cope with pressure differences occurring in the housing of the lighting device, for example a drop in pressure, for example an instantaneous or sudden drop in pressure. The improved lighting device thereby reduces a negative pressure gradient (between the housing and its exterior) caused by such a pressure drop; and consequently reduces the ingress of contaminants and/or undesired stress on parts of the lighting device. The lighting device according to the present invention does for example not require any structural modification, e.g. an introduction of apertures or conduits in the housing, to solve the above-mentioned problems and disadvantages, because the expanding effect of the bag solves these identified problems and disadvantages. The invention may therefore be well applicable to retrofit lighting devices, such as e.g. existing IPxx rated luminaires.

As partly mentioned before, the bag material comprises a Modulus of Elasticity of at least 0.1 GPa, preferably at least 0.2 GPa, and at most 5 GPa. Most common polymers fall within this stiffness range. The effect of such a bag material comprising such a stiffness is that the bag is less elastic. Therefore, less force is required to expand the bag for reducing the housing volume and for thereby compensating a pressure drop in the housing pressure. Moreover, since less force is required for deformation, the reaction of the bag to the pressure drop is quicker. This quicker reaction may e.g. especially be relevant when having an instantaneous pressure drop, as defined in the present application, because no initial force is required to overcome the elasticity of the bag material for it to expand. The bag may for example be a polymer bag. This is a clear advantage. In examples, the bag material comprises a Modulus of Elasticity of: at least 1 GPa and/or at most 5 GPa; or between 1 GPa and 4 GPa; or between 0.5 and 4 GPa; or between 0.2 GPa and 3 GPa; or at most 4 GPa; or at most 3 GPa. Hence, the bag may be substantially inelastic.

As mentioned, the housing fluid may be a gas.|

The bag material may comprise a thickness of at least 0.1 millimeter, or at least 0.2 millimeter, or at least 1 millimeter, and/or at most 3 millimeter. Such a thickness may be uniform throughout the bag material. Such a thickness may be advantageous as the weight of the bag material is sufficiently low, which may allow the bag to expand instantaneously when the pressure difference according to the invention renders an expanding force. Hence, less force is required to expand the bag for reducing the housing volume and for thereby compensating a pressure drop in the housing pressure. Moreover, since less force is required for deformation, the reaction of the bag to the pressure drop is quicker. This quicker reaction may e.g. especially be relevant when having an instantaneous pressure drop, as defined in the present application, because less force is required to compensate for the weight of the bag material. Such a thickness may be applicable to the bag material being e.g. a polymer material.

The housing may e.g. be a luminaire, a compartment, a troffer, an optical enclosure, etc. The bag may e.g. be phrased as a container or a flexible container, a balloon, an expansion volume, or an expansion means. The exit window may be an optic or a translucent or transparent window, or a lens plate or a diffuser.

The light source, the light exit window, and the bag may all be comprised within a housing with a single housing compartment. Hence, the single housing compartment may be one volume without further subdivisions of sub compartments. The light exit window may for example be a transparent and/or translucent wall of the housing.

As partly mentioned before: The housing volume may be prone to pressure differences. Pressure differences may for example be caused by temperature differences. Namely, a difference in temperature between fluids may cause a difference in pressure of said fluids. For example, cold air may contract, and hot air may expand; hence cold air may have a lower pressure compared to hot air; noting hereby that air may act as a perfect gas.

Hence, in an embodiment, the pressure drop in the housing pressure of the housing fluid may be caused by a temperature drop of the housing fluid. The temperature drop may for example be instantaneous due to sudden change in weather conditions.

For example, an operating outdoor luminaire may experience a temperature drop of its interior volume due to an instantaneous change in weather conditions at its exterior, such as a sudden rainfall, snowfall, hail, breeze, flooding, etc. The pressure of the fluid within the housing of said luminaire may therefore also drop instantaneously. The present invention may therefore be advantageous, because the features of the present invention provide an improved lighting device that may cope with said instantaneous pressure drop and, as indicated above, its undesired effects. That is: the bag expands to reduce the interior volume of the luminaire and thereby compensating the instantaneous pressure drop of the fluid within the housing of said luminaire. Hence, the bag reduces the occurring instantaneous peak of negative pressure relatively to the situation before the instantaneous temperature drop.

Alternatively, said luminaire does not have to be in operation, because due to e.g. direct sunshine the luminaire may heat op, while instantaneously cooling due to sudden rainfall.

Another example, an operating luminaire may experience a temperature drop of its interior volume due to a scheduled cleaning of its exterior with e.g. a pressurized spray of cleaning water. The pressure of the fluid within the housing of said luminaire may therefore also drop. The present invention may therefore be advantageous, because the features of the present invention provide an improved lighting device that may cope with said instantaneous pressure drop and, as indicated above, its undesired effects.

Yet another example, an operating luminaire may experience a temperature drop of its interior volume due to an activation of an air conditioning system. The pressure of the fluid within the housing of said luminaire may therefore also drop. This may particularly be the case in office environments, and/or in troffer-based luminaires, or in HVAC and lighting integrated systems. The housing may thus be a troffer. The present invention may therefore be advantageous, because the features of the present invention provide an improved lighting device that may cope with said instantaneous pressure drop and, as indicated above, its undesired effects. The lighting device may in some examples be integrated in or be part of an HVAC or AC system.

Such a temperature drop and/or pressure drop may occur regularly, cyclically, and/or periodically. The temperature drop and/or pressure drop may be instantaneous or sudden. Moreover, the temperature drop and its associated pressure drop may for example result in sucking in undesired contaminants such as water, dust, dirt, insects, or moisture within e.g. the housing of the lighting device. Said sucking in may occur via leaks, failing seals, cable glands, gaskets, joints, etc. Moreover, such a temperature drop and its associated pressure drop may also result in mechanical failure due to occurring stresses. Such a pressure drop may therefore, over time, result in failing gaskets, joints and/or seals, hence leading to leaks and/or limited lifetime; which even further increases the susceptibility of the lighting device to suck in contaminants.

In an embodiment, the bag may be configured to expand in respect to a temperature drop of the housing fluid of at least 10 Kelvin. Thus, the bag may be able to expand such that a pressure drop agreeing with a temperature drop of at least 10 Kelvin may be compensated. Said 10 Kelvin may mutatis mutandis be 10 degrees drop in temperature on the Celsius scale. This is advantageous, because in particular a temperature drop of at least 10 Kelvin may result in more of the undesirable effects as mentioned above. Thus, said temperature drop may be: at least 20 Kelvin, at least 30 Kelvin, at least 40 Kelvin, between 20 Kelvin and 40 Kelvin, or between 20 Kelvin and 60 Kelvin.

The pressure drop may be sudden and/or instantaneous. In an embodiment, the pressure drop may be at least 10 mBar within 40 seconds. Alternatively, the pressure drop may at least be 44 mBar within 180 seconds. The pressure drop may hence be expressed in a rate. Said rate of pressure drop may alternatively be: at least 1 mbar within 4 seconds, at least 50 mBar within 150 seconds, at least 12 mBar within 60 seconds. Such pressure drop rates may last for at least 10 seconds, and/or last between 10-50 seconds, and/or last between 50-100 seconds, and/or last between 100-180 seconds. These are the instantaneous rates, wherein a pressure drop occurs within a relatively short period of time. Alternatively, the pressure drop may at least be 1 mBar within 1 seconds, wherein said rate may last for 10 seconds; or at least be 0.6 mBar within 1 seconds during between 10-70 seconds from the initial occurrence of the pressure drop; or at least be 0.1 mBar within 1 seconds during between 70-180 seconds from the initial occurrence of the pressure drop. Such values may be derived from experimental results.

The effects of such a temperature drop and such a pressure drop may be more severe when occurring instantaneously or suddenly, because the resulting negative pressure gradient becomes higher. In such conditions the improved lighting device is more advantageous. Hence, in an embodiment, the bag may be configured to expand in respect to a temperature drop of the housing fluid occurring within a time period no longer than 160 seconds. Said time period may alternatively be no longer than 120 seconds, no longer than 120 seconds, or no longer than 30 seconds.

As mentioned, the bag may expand due to a pressure drop in the housing pressure as a consequence of a temperature drop of the housing fluid. Whenever the bag and the surrounding housing volume reach an equilibrium state, the bag will no longer expand. Hence, it is advantageous to thermally isolate the bag more, such that the temperature difference and the corresponding pressure difference is larger when a temperature drop and/or pressure drop occurs in the housing volume. The bag will therefore expand more, and hence reduce the housing volume more, and thereby compensating more the pressure drop in the housing pressure of the housing fluid. Thus, in one embodiment, the bag material comprises a thermal conductivity of at most 0.3 W/mK for reducing a rate of heat transfer from the housing fluid to the bag fluid. Such a thermal conductivity may be achieved by means of selecting a suitable bag material, which encloses the interior of the bag. The bag material may alternatively comprise a laminate of layers, wherein at least one layer is an insulation layer. Said thermal conductivity may alternatively be 0.3 W/mK or at most 0.2 W/mK, or at most 0.15 W/mK, or at most 0.1 W/mK.

In an embodiment, the housing volume may be at least 0.001 cubic meters. The ratio between the housing volume and the volume of the bag, i.e. housing volume:bag volume, may for example range between a ratio of 10:1 and 10:8, or be between a ratio of 10:1 and 10:7, or at least be 10:0.5.

In an embodiment, the housing may comprise at least one breather for allowing moisture to leave the housing. Such a breather allows moisture to leave the housing, more specifically the housing volume. However, a breather is also a weak point for ingress of contaminants. Nevertheless, due to the present invention the instantaneous pressure drop is compensated by the expanding of the bag, hence reducing the pressure gradient with the exterior of the lighting device. Therefore, the disadvantages associated with a breather for a normal luminaire are mitigated by the improved lighting device of the present invention.

Hence, in some examples, the lighting device may both comprise a breather and a balloon, such that pressure differences, such as e.g. a pressure drop, may be compensated throughout e.g. the whole lifetime of the lighting device (i.e. facilitating compensating instantaneous pressure drops with the bag according to the invention, while facilitating balancing pressure with the exterior on the long term, i.e. e.g. hours, by means of the breather).

In some examples, the housing may be gastightly sealed, whenever e.g. no breather is present.

In an embodiment, the housing may comprise at least one cable gland for feeding a cable through the housing. Such a cable gland may be necessary for cabling the lighting device but may also be a weak point for ingress of contaminants. Nevertheless, due to the present invention the instantaneous pressure drop is compensated by the expanding of the bag, hence reducing the pressure gradient with the exterior of the lighting device. Therefore, the disadvantages associated with a breather for a normal luminaire are mitigated by the improved lighting device of the present invention.

In an embodiment, the lighting device may be one of the group of: street lighting, stadium lighting, façade lighting, and outdoor lighting. The lighting device may e.g. be a luminaire, an outdoor light pole, a floodlight, a projector, or an indoor luminaire. Said indoor luminaire may e.g. be positioned close to an air conditioning outlet or vent, which may lead to an instantaneous temperature drop during a start of cooling a building.

In an embodiment, the lighting device may comprise a LED light source. Namely: the light source may be a LED light source. Alternatively, the lighting device may comprise, or the light source may be: a high-power LED light source, or an array thereof. Alternatively, the lighting device may comprise, or the light source may be: a conventional light source. Yet alternatively, said lighting device may comprise detecting means or lighting device electronics. For example, a lighting driver, or a light engine, etc.

In a further embodiment, the bag may be in connection with an optic of the lighting device. For example, in an embodiment thereof, the bag may be in connection with said exit window. Said optic may for example be a lens plate or diffuser. Such optic components may be assembled with tight fittings, such that their circumference may be prone to ingress. Hence, for example, positioning or having the bag in connection with said optic may be advantageous, as the pressure drop will be compensated and as the bag is within the right enclosure of the housing, i.e. close to the optic. The same applies in respect to the exit window.

In some embodiments, the bag may additionally comprise salt for binding moisture. Such salt may be present within the bag and/or on a surface of the bag. Said salt may e.g. be impregnated in a material of the bag, or connected to the bag in a separate bag.

In an embodiment, the housing may comprise a housing material being one of: metal, steel, aluminum, ceramic, polymer, fiber reinforced polymer, copper, or a combination thereof.

In some embodiments, the bag may be in connection with said light source. For example, the bag may be attached to the light source, or a PCB holding the light source, such as e.g. a LED chip on board. Such a location may for example be beneficial to position the bag as the light source may be more easily reachable.

In some examples, the bag is configured to expand in between components in the housing, such as a lighting driver, battery, sensor, or wiring. For example, the bag may be configured in such shape that the bag may expand in a void, which void may be present in between the driver and a PCB holding a light source. The bag may comprise a star shape, or a T-shape.

In an embodiment, the bag may comprise a rectangular shape, having a length, height and width. Such a bag is advantageous, as it may be positioned onto a panel, in between components of the lighting device, such as a driver, a light source, a PCB, a CIP, a structural element, etc. For example, such a rectangular shaped bag may be advantageous for flood lights or sports lighting, which may be large paneled lighting devices. Similarly, the bag may comprise a cylindrical shape, which may agree well with a shape of the lighting device and the housing thereof, such as a light pole or a pole top lighting device.

As mentioned, lighting devices may cope with the undesired effects of pressure difference occurring within the housing volume of said lighting devices. Such lighting devices may already be configured and existing. Replacing lighting devices may be expensive. Modifying the construction or housing of the lighting devices may also be expensive and undesired because such modifications may affect the structural integrity of the lighting device. Thus, currently, no option is available to ergonomically upgrade or retrofit an existing lighting device to cope with the mentioned pressure differences and related undesired ingress, without affecting the structure of its housing such as e.g. without drilling holes.

Hence, in an embodiment, the housing may further comprise an aperture and a panel for closing said aperture, wherein the bag is connected to said panel. Such an embodiment is advantageous, because the present invention may therefore applicable to existing lighting devices, because no modifications is required to the structure of the lighting device, only attaching the bag according to the invention to a panel closing the lighting device. The panel for closing said aperture may for example be a lid or an entrance cover, or a plug. The bag may be connected to said panel, such that the bag is in the housing of the lighting device. This is ergonomic and improves the capability of an existing lighting device to be able to cope with a pressure drop. The panel may gastightly close said aperture, e.g. by means of a seal surrounding the edges of said panel.

In an embodiment, the bag material is one of: a polymer, a fiber reinforced polymer, and/or a textile. Said bag material may be one of: Polypropylene (PP), Polyethylene terephthalate (PET), Mylar (Al coated PET), polyethylene (PE), Polyimide (PI), or a combination of the above. Said bag material may comprise a surface with a reflectivity of at least 0.6, which allows to reflect radiative heat transfer. Said bag material may comprise a surface coating.

In an embodiment, the bag material may comprise a paper. Said bag may thus be e.g. a paper bag, wherein the paper bag is gastightly sealed, e.g. by means of a polymer coating of the paper bag. Due to thermally insulating properties of the bag material paper, the fluid inside the bag may cool down less due to a temperature drop. The effect of such a bag comprising the bag material paper may thus be that the temperature difference and the corresponding pressure difference between the bag fluid and housing fluid (i.e. the air of the housing volume) when a temperature drop and/or pressure drop occurs in the housing volume. Therefore, due to said larger temperature and corresponding pressure difference, the bag will expand more and reduce the housing volume more, thereby compensating more the pressure drop in the housing pressure of the housing fluid (i.e. the air of the housing volume). Such a bag material comprising a paper may also be cheaper and more environmental friendly than other e.g. textile or polymer alternatives. Thus, in aspects of the invention, the bag may be a paper bag and/or the bag material may comprise (may e.g. be) paper. Said paper and/or said paper bag may be coated with a gastight coating, such as a polymer coating.

In an embodiment, the bag fluid is one of: air; a high molecular weight gas (as known in the field of gasses or gasdynamics), such as e.g. SF6, CH3Cl, CCl2F2, SO2F2, CH3Br, C2H5I, SO2; or a medium molecular weight gas, such as Argon, Krypton, Carbon dioxide, Trifluoroiodomethane, Pentafluoroetane, Heptafluoropropane, R407C, or Fluoroform R23.

The bag fluid may initially be at atmospheric pressure at room temperature, for example air at atmospheric pressure at room temperature. This may constitute the initial condition of the bag. In some examples, the bag may be pressurized.

It is a further object of the invention to provide an improved method of compensating a pressure drop in a lighting device, which at least alleviates the problems and disadvantages mentioned above. Thereto, the invention further provides a method of compensating a pressure drop in a lighting device, the lighting device comprising a housing and a bag made of a bag material, wherein the housing comprises a light source and a light exit window for outputting light of the light source to the exterior, wherein the housing has a housing volume filled with a housing fluid having a housing pressure, wherein the bag is gastightly sealed, is filled with a bag fluid, and is contained within the housing volume, wherein the method comprises: expanding the bag for reducing the housing volume and for thereby compensating a pressure drop in the housing pressure of the housing fluid. Here, as mentioned before, the bag material comprises a Modulus of Elasticity of at least 0.1 GPa and at most 5 GPa.

In an embodiment, the method according to the invention is provided, wherein the pressure drop in the housing pressure of the housing fluid is caused by a temperature drop of the housing fluid.

In an embodiment, the method according to the invention is provided, wherein the method further comprises positioning and/or securing said bag in the housing. This may either be done by first opening a lid or panel that provides access to said housing. The lighting device to which the housing belongs may e.g. be a retrofit lighting device.

In an embodiment, the method according to the invention is provided, wherein the bag is configured to expand in respect to a temperature drop of the housing fluid of at least 10 Kelvin, and/or wherein the bag is configured to expand in respect to a temperature drop of the housing fluid occurring within a time period no longer than 160 seconds.

The advantages and/or embodiments applying to the lighting device according to the invention also apply to the present method of compensating a pressure drop in a lighting device.

As mentioned, lighting devices may cope with the undesired effects of pressure difference occurring within the housing volume of said lighting devices. Such lighting devices may already be configured and existing. Replacing lighting devices may be expensive. Modifying the construction or housing of the lighting devices may also be expensive and undesired because such modifications may affect the structural integrity of the lighting device. Thus, currently, no option is available to ergonomically upgrade or retrofit an existing lighting device to cope with the mentioned pressure differences and related undesired ingress, without affecting the structure of its housing such as e.g. without drilling holes.

Hence, it is a further object of the invention to provide an improved method of equipping a lighting device with a bag made of a bag material, wherein the lighting device comprises a housing having a housing volume filled with a housing fluid having a housing pressure, wherein the housing comprises a light source and a light exit window for outputting light of the light source to the exterior, wherein the housing further comprises an aperture and a panel for closing said aperture, wherein the bag is gastightly sealed with a bag material and is filled with a bag fluid, wherein the method comprises: opening said panel for opening said aperture; equipping the lighting device with said bag for containing the bag within the housing volume; closing said panel for closing said aperture. Hereby, in an embodiment, the bag may be connected to said panel. Moreover, in an embodiment, the lighting device may be a retrofit lighting device.

The advantages and/or embodiments applying to the lighting device according to the invention also apply to the present method of equipping a lighting device with a bag.

In aspects of the invention, the invention may further provide: A bag configured to expand within a housing volume for reducing the housing volume, the housing volume being filled with a housing fluid having a housing pressure, and for thereby compensating a pressure drop in the housing pressure of the housing fluid; wherein the bag is gastightly sealed, made of a bag material, is filled with a bag fluid, and is contained within the housing volume.

In aspects, as partly mentioned before, the bag material is less elastic and does not constitute tension in the bag material counteracting the force of deformation caused by the pressure difference originating from the pressure drop. The shape of the bag is therefore freely deformable, wherein the bag material does not comprise tension for returning the bag into its original shape. The bag may therefore advantageously deform in regions of the housing volume between components of the lighting device, thereby saving space and providing a compact lighting device.

In aspects of the invention, the invention provides a lighting device comprising a housing and a bag made of a bag material; wherein the housing comprises a light source and a light exit window for outputting light of the light source to the exterior; wherein the housing has a housing volume filled with a housing fluid having a housing pressure; wherein the bag is gastightly sealed, and is filled with a bag fluid, and is contained within the housing volume; wherein the bag is configured to expand for reducing the housing volume and for thereby compensating a pressure drop in the housing pressure of the housing fluid.

### BRIEF DESCRIPTION OF THE DRAWINGS

The invention will now be further elucidated by means of the schematic non-limiting drawings:

FIG. 1 depicts schematically a side view of a first embodiment of a lighting device comprising a housing and a bag;

FIG. 2 depicts schematically a top view of a second embodiment of a lighting device comprising a housing and a bag;

FIG. 3 depicts schematically, by non-limiting example, an embodiment of a method compensating a pressure drop in a lighting device;

FIG. 4 depicts schematically, by non-liming example, within a chart, experimental results of a bag according to the invention present within a lighting device in comparison to the situation wherein no bag is present.

FIG. 5 depicts schematically, by non-limiting example, an embodiment of a method of equipping a lighting device with a bag.

### DETAILED DESCRIPTION OF THE EMBODIMENTS

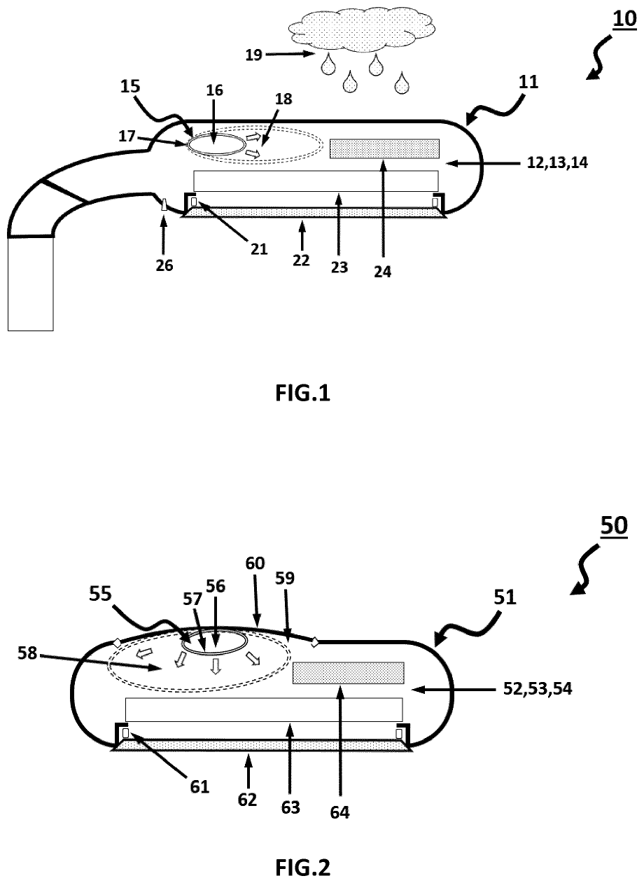

As mentioned, the present invention provides an improved lighting device 10. FIG. 1 depicts schematically a side view of a first embodiment of a lighting device 10 according to the invention. The lighting device comprises a housing 11 and a bag 15. The housing 11 is made of metal. Alternatively, the housing may be made of, or partly made of, steel, aluminum, ceramic, polymer, fiber reinforced polymer, copper, or a combination thereof. The lighting device 10 further comprises a light source 23 for providing light through a light exit window 22, which is driven by a driver 24 and controlled by control electronics (not shown). Alternatively, other configuration of components may be present. The light source 23 is a LED light source, but may alternatively be a conventional light source. The window 22 is a transparent plate such as glass or polymer, but may alternatively comprise further optical features. The window 22 is gastightly sealed to the housing 11 by means of the gasket 21. The lighting device 10 is an outdoor lighting device, which is part of street lighting and mounted on a light pole. Alternatively, the lighting device may be any other outdoor lighting device, such as a flood light, façade lighting, or sports lighting. Yet alternatively, said lighting device may be a troffer-based lighting device and/or an indoor luminaire. The housing may optionally comprise a heat sink.

The housing 11 further optionally comprises a breather 26 for allowing moisture to leave the housing 11. However, the flow rate through the breather 26 is limited, so that the breather 26 cannot timely equalize a pressure at the interior of the lighting device 10 with the exterior of the lighting device 10. When a pressure drop occurs within the housing 11, a negative pressure gradient exists with the exterior of the housing 11, and the breather becomes a weak point for ingress of contaminants. Similarly, the housing 11 further optionally comprises at least one cable gland (not shown) for feeding a cable (not shown) through light pole into the housing 11. Such a cable gland may also be a weak point for ingress of contaminants, as it may wear in time and be prone to leaks.

The housing 11 has a housing volume 12 filled with a housing fluid 13 having a housing pressure 14. The housing volume 12 contains the volume of fluid enclosed by the housing 11 of the lighting device 10. Here, and generally, the housing fluid 13 is the air in the atmosphere. The housing pressure 14 depends on the thermodynamic conditions present in the housing 11. For example: during operation of the lighting device 10 the light source 23 and/or driver 24 are a source of heat, which may increase the temperature inside the housing 11, and which hence may increase the housing pressure 14 of the housing fluid 13 of the housing volume 12 inside the housing 11.

Alternatively, the housing volume of the housing of the lighting device may be gastightly sealed and may contain a pre-defined housing fluid. Such a pre-defined housing fluid may comprise a composition having less oxygen or less contaminants relative to the standard composition of air. The mentioned composition may be selected such as to improve the lifetime of the lighting device, e.g. preventing browning of seals.

Referring to FIG. 1, as mentioned before, the housing volume 12 may be prone to pressure differences. Here, the housing fluid 13 experiences a pressure drop with respect to the ambient fluid or ambient conditions, i.e. e.g. the ambient fluid surrounding the housing 11 of the lighting device 10. Said pressure drop is caused by a temperature drop of the housing fluid 13 due to weather conditions 19, such as e.g. rain. The temperature drop causing the pressure drop is instantaneous. It may alternatively be because of a water spray hitting the housing 11 of the lighting device 10 due to cleaning activities, or an indoor HVAC system suddenly cooling the lighting device. Said temperature drop may be a temperature shock. The pressure drop is undesired, because it not only puts mechanical stress on gaskets, seals, joints, and/or walls, such as the gasket 21 holding the window 22; but it also allows contaminants such as water, moisture, dust, dirt, insects, etc. to be sucked into the housing via leaks or apertures due to the resulting negative pressure gradient, such as the breather 26. Here, the (rate of the) pressure drop as caused by the temperature drop is at least 10 mBar within 40 seconds.

Alternatively, the pressure drop, or better the rate of pressure drop, is at least 50 mBar within 150 seconds, at least 12 mBar within 60 seconds. Such pressure drop rates may last for at least 10 seconds, and/or last between 10-50 seconds, and/or last between 50-100 seconds, and/or last between 100-180 seconds. These are the instantaneous rates, wherein a pressure drop occurs within a relatively short period of time. Alternatively, the pressure drop may at least be 1 mBar within 1 seconds, wherein said rate may last for 10 seconds; or at least be 0.6 mBar within 1 seconds during between 10-70 seconds from the initial occurrence of the pressure drop; or at least be 0.1 mBar within 1 seconds during between 70-180 seconds from the initial occurrence of the pressure drop. Such values may be derived from experimental results.

Alternatively, instead of the rate of pressure drop, the rate of temperature drop may be quantified as at least 10 Kelvin within a time period no longer than 180 seconds.

Moreover, still referring to FIG. 1, the bag 15 is comprised by the housing 11. The bag is in connection with a part of the housing 11 and is contained within the housing volume 12. The bag 15 may for example be attached to or be freely lying on a surface of said housing 11. Alternatively, the bag may be arranged with respect to a heat source within the housing, such as the light source or driver electronics, or other electric components. The bag may in such alternative embodiments remain warmer than the housing volume in the housing, hence having an increased ability to expand with respect thereto. The bag may for example be connected to said light source.

The bag 15 is gastightly sealed with a bag material 17. The bag material 17 is polyethylene (PE), but may alternatively be one of: Polypropylene (PP), Polyethylene terephthalate (PET), Mylar (Al coated PET), polyethylene (PE), Polyimide (PI), or a combination of the above. Alternatively, the bag material may comprise a plurality of material layers, wherein at least one of said plurality of layers may comprise an insulation layer, such as e.g. PET, paper insulation or an air gap/bubbles. Furthermore, the bag material 17 comprises a thermal conductivity of at most 0.3 W/mK for reducing a rate of heat transfer from the housing fluid to the bag fluid. Alternatively, or additionally, said bag material may comprise a surface with a reflectivity of at least 0.6, such as a reflective coating.

The bag 15 reduces the mentioned undesired or disadvantageous consequences of said pressure drop. Namely: The bag is filled with a bag fluid 16. Here, the bag fluid 16 is also air, but may alternatively be one of: high molecular weight gas, or medium molecular weight gas, or a combination of the above. The higher the molecular weight of the gas, the more delay is present in cooling down or heating up, hence the pressure compensating effect will be improved. The bag 15 is configured to expand for reducing the housing volume 12 and for thereby compensating the pressure drop in the housing pressure 14 of the housing fluid 13. More specifically: When said pressure drop occurs in the housing 11, the bag 17 may initially not be affected by the occurring pressure drop, because the bag fluid 16 is isolated from the housing fluid, and in some embodiments also insulated from the housing fluid. Therefore, the bag 15 expands 18 whenever the housing volume 12 experiences this sudden pressure drop in the housing pressure 14 of its housing fluid 13. As the bag 15 is contained within the housing volume 12, the expansion 18 of the bag 15 will reduce the housing volume 12. A reduction of the housing volume 12 will subsequently result into an increase in of the housing pressure 14 of the housing fluid 13. Thus, the sudden pressure drop in the housing pressure 12 of the housing fluid 13 will be compensated.

Here, the housing volume is at least 0.001 cubic meters. The bag 15 may expand within a range between 10% and 80% of the housing volume. Here, the bag is at least 10% of the housing volume and expands to 25% of the housing volume. Alternatively, the ratio between the housing volume and the volume of the bag, i.e. housing volume:bag volume, may for example range between a ratio of 10:1 and 10:8, or be between a ratio of 10:1 and 10:7, or at least be 10:0.5.

The present invention therefore provides an improved lighting device, which is able to cope with a pressure drop occurring in the housing of the lighting device, because it reduces a negative pressure gradient caused by such a pressure drop; and consequently reduces the ingress of contaminants and/or undesired stress on parts of the lighting device. The lighting device according to the present invention does for example not require any structural modification, e.g. an introduction of apertures or conduits in the housing, to solve the above-mentioned problems and disadvantages, because the expanding effect of the bag solves these identified problems and disadvantages.

FIG. 2 depicts schematically a top view of a second embodiment of a lighting device 50 comprising a housing 51 and a bag 55; which is partly similar to the embodiment depicted in FIG. 1, but now wherein the lighting device 50 is a flood light for illuminating a large stadium area and wherein the housing 51 comprises a panel 60 for closing an aperture 59 of the housing 51.

Referring to FIG. 2, the lighting device 50 comprises a housing 51 made of fiber reinforced polymer material, such that the lighting device 50 is lightweight, but still able to cope with mechanical loads and/or heat transfer from its interior to its exterior. The lighting device 50 further comprises a light source 53 for providing light through an optical element being a lens plate 62. The lens plate 62 is gastightly sealed to the housing 51 by means of the gasket 61. The light source 53 is driven and controlled by the driver electronics 64. Optionally, the housing 51 may accommodate sensors and/or actuators, such as an electromotor which is able to aim the flood light. Said actuator may comprise parts protruding through the housing, but still having seals and/or gaskets to gastightly seal the housing at the location of said protruding parts, e.g. axes.

The housing 51 is gastightly sealed. However, during its lifetime, the housing 51 of the lighting device 50 may experience leaks, for example due to deteriorated seals/gaskets. Such leaks may become a point for ingress of contaminants whenever a pressure drop occurs in the housing 51 in respect to its surroundings.

As similarly mentioned before, the housing 51 has a housing volume 52 filled with a housing fluid 53 having a housing pressure 54. The housing volume 52 contains the volume of fluid enclosed by the housing 51 of the lighting device 50. Here, again, the housing fluid 53 is the air in the atmosphere. The housing pressure 54 depends on the thermodynamic conditions present in the housing 11.

Referring to FIG. 2, as mentioned before, the housing volume 52 may be prone to pressure differences. Here, the housing fluid 53 experiences a pressure drop with respect to the ambient fluid or ambient conditions, i.e. e.g. the ambient fluid surrounding the housing 51 of the lighting device 50. Said pressure drop is caused by a temperature drop of the housing fluid 53. The temperature drop causing the pressure drop is instantaneous, namely 10 Kelvin within a time period of 60 seconds. Alternatively, the rate of temperature drop may be at least 10 Kelvin within a time period of 30 seconds. The pressure drop associated with such an instantaneous temperature drop is undesired, because it not only puts mechanical stress on gaskets, seals, joints, and/or walls, such as the gasket 61 holding the lens plate 62; but it also allows contaminants such as water, moisture, dust, dirt, insects, etc. to be sucked into the housing via leaks or apertures due to the resulting negative pressure gradient.

Moreover, still referring to FIG. 2, the housing 51 comprises an aperture 59 and a panel 60 for gastightly closing said aperture 59. This panel 60 can be detached to access the housing 51 of the lighting device 50. Alternatively, the panel 60 may be a lid which is pivoting in the housing. Furthermore, the bag 55 is comprised by the housing 51. The bag 55 is attached to the panel 60 and is, in closed condition of the panel 60, contained within the housing volume 52. Thus the bag may be easily applied to the lighting device by opening the panel and attaching the bag thereto.

The bag 15 is gastightly sealed with a bag material 57. The bag material 57 is Polypropylene (PP) and comprises an insulation layer of a further paper layer. Here, the bag material 57 comprises a thermal conductivity of 0.15 W/mK for reducing a rate of heat transfer from the housing fluid to the bag fluid and/or the heat transfer from the panel to the bag fluid.

Still referring to FIG. 2, the bag 55 reduces the mentioned undesired or disadvantageous consequences of said pressure drop caused by said temperature drop. Namely: The bag is filled with a bag fluid 56. Here, the bag fluid 56 is also air, but may alternatively be carbon dioxide, nitrogen or argon. The bag 55 is configured to expand for reducing the housing volume 52 and for thereby compensating the pressure drop in the housing pressure 54 of the housing fluid 53. More specifically: When said pressure drop occurs in the housing 51, the bag 57 may initially not be affected by the occurring pressure drop, because the bag fluid 56 is isolated from the housing fluid, and also insulated from the housing fluid. Therefore, the bag 55 expands 58 whenever the housing volume 52 experiences this sudden pressure drop in the housing pressure 54 of its housing fluid 53. Here, the housing volume 52 is at least 0.002 cubic meters. The bag 15 is expandable within a range between 10% and 40% of the housing volume 52. As the bag 55 is contained within the housing volume 52, the expansion 58 of the bag 55 will reduce the housing volume 52. A reduction of the housing volume 52 will subsequently result into an increase in of the housing pressure 54 of the housing fluid 53. Thus, the sudden pressure drop in the housing pressure 52 of the housing fluid 53 will be compensated. Hence, reducing the occurring negative pressure gradient caused by the pressure drop and reducing ingress of contaminants and/or mechanical loads on parts of the housing 51 of the lighting device 50.

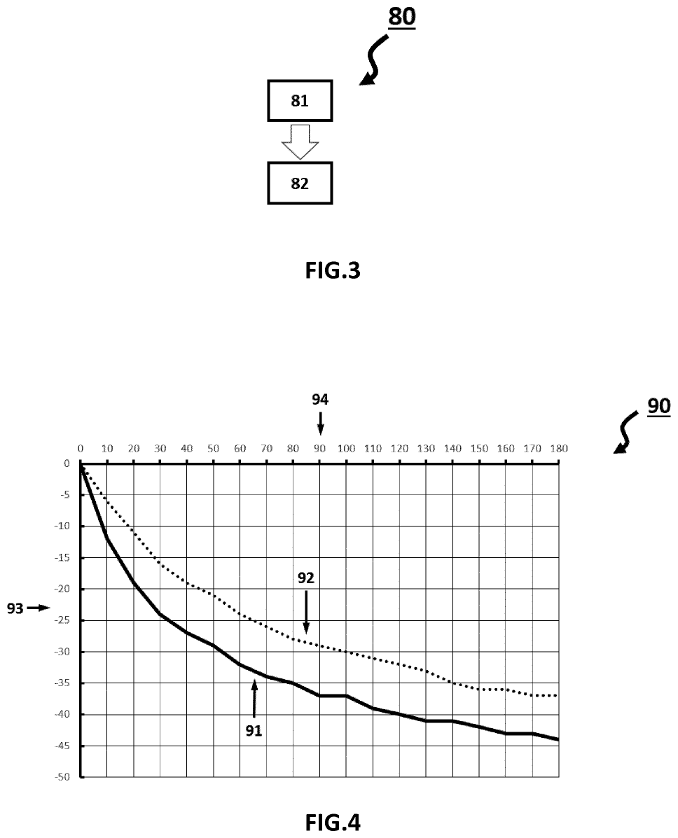

FIG. 3 depicts schematically, within a flowchart, an embodiment of a method 80 of compensating a pressure drop in a lighting device, such as e.g. a lighting device depicted in FIG. 1 and FIG. 2. The method comprises the step (81) of positioning a bag within a housing of a lighting device according to the invention. For example, in the embodiment depicted in FIG. 2, the panel may be opened, the bag may be positioned in connection with said panel, such that when closing the panel, the bag may be comprised within the housing volume of the housing thereof.

The method further comprises the step (82) of expanding the bag for reducing the housing volume and for thereby compensating a pressure drop in the housing pressure of the housing fluid. As mentioned before: As the bag is contained within the housing volume, the expansion of the bag will reduce the housing volume. A reduction of the housing volume will subsequently result into an increase in of the housing pressure of the housing fluid. Thus, the sudden pressure drop in the housing pressure of the housing fluid will be compensated. Hence, reducing the occurring negative pressure gradient caused by the pressure drop and reducing ingress of contaminants and/or mechanical loads on parts of the housing 51 of the lighting device 50.

FIG. 4 depicts schematically, by non-liming example, within a chart, experimental results 90 of a bag according to the invention present within a lighting device in comparison to the situation wherein no bag is present. The experiment is conducted with a lighting device according to the invention, being a pole top street lighting luminaire, with a gastightly sealed housing having a housing volume of approximately 0.003 cubic meters. A bag, being a gastightly sealed PE bag, is positioned in said housing, wherein the bag is contained within the housing volume. Both the bag as the housing volume comprise air as the housing fluid and the bag fluid. The lighting device is turn on and after three hours of operation the lighting device is continuously sprayed with pressurized water for inducing a temperature drop and consequently a pressure drop in the housing pressure of the housing fluid.

The experimental results 90 are presented in a chart. The chart shows a first graph 91 representing the lighting device without a bag according to the invention, and a second graph 92 representing the lighting device with a bag according to the invention and as mentioned above. The Y-axis 93 of the chart indicates the pressure drop in millibars. The X-axis 94 of the chart indicates the time in seconds. The experimental results 90 prove that the present invention, wherein the lighting device comprises a bag, compensates a pressure drop in the housing pressure of the housing fluid; because the bag expands and reduces the housing volume. This is clearly indicated in the second graph (representing the invention) having a lower pressure drop and having a lower initial slope in the rate of pressure drop.

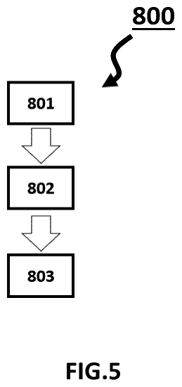

FIG. 5 depicts schematically, within a flowchart, an embodiment of a method 800 of equipping a lighting device, e.g. a retrofit lighting device, with a bag. Such a lighting device comprises a housing having a housing volume filled with a housing fluid having a housing pressure, wherein the housing further comprises an aperture and a panel for closing said aperture. Said bag is gastightly sealed with a bag material and is filled with a bag fluid. It is the bag according to the invention. The method of equipping said lighting device with said bag comprises: (801) opening said panel for opening said aperture; (802) equipping the lighting device with said bag for containing the bag within the housing volume; (803) closing said panel for closing said aperture. Hereby, in an embodiment, the bag may be connected to said panel, or alternatively to the light source, or alternatively to a PCB of said light source, or alternatively to another part of an interior surface of said housing.

1. A lighting device comprising a housing and a bag made of a bag material;
wherein the housing comprises a light source and a light exit window for outputting light of the light source to the exterior;
wherein the housing has a housing volume filled with air having a housing pressure;
wherein the bag is gastightly sealed, and is filled with a bag fluid, and is contained within the housing volume;
wherein the bag is configured to expand for reducing the housing volume and for thereby compensating a pressure drop in the housing pressure of the air;
wherein the bag material comprises a Modulus of Elasticity of at least 0.1 GPa and at most 5 GPa;
wherein the bag material comprises a plurality of material layers, wherein at least one of said plurality of layers comprises an insulation layer.

2. The lighting device according to claim 1, wherein the pressure drop in the housing pressure of the air is caused by a temperature drop of the air.

3. The lighting device according to claim 1, wherein the bag is configured to expand in respect to a temperature drop of the air of at least 10 Kelvin.

4. The lighting device according to claim 1, wherein the bag is configured to expand in respect to a temperature drop of the air occurring within a time period no longer than 160 seconds.

5. The lighting device according to claim 1, wherein the bag material comprises a thermal conductivity of at most 0.3 W/mK for reducing a rate of heat transfer from the air to the bag fluid.

6. The lighting device according to claim 1, wherein the housing volume is at least 0.001 cubic meters.

7. The lighting device according to claim 1, wherein the lighting device is one of the group of: street lighting, stadium lighting, façade lighting, and outdoor lighting.

8. The lighting device according to claim 1, wherein the housing further comprises an aperture and a panel for closing said aperture, wherein the bag is connected to said panel.

9. The lighting device according to claim 1, wherein the bag expands within a range between 10% and 40% of the housing volume.

10. The lighting device according to claim 1, wherein the bag is in connection with an optic of the lighting device.

11. The lighting device according to claim 1, wherein the bag is a paper bag and the bag material comprises paper.

12. A method of compensating a pressure drop in a lighting device, the lighting device comprising a housing and a bag made of a bag material,
wherein the housing comprises a light source and a light exit window for outputting light of the light source to the exterior,
wherein the housing has a housing volume filled with air having a housing pressure, wherein the bag is gastightly sealed, is filled with a bag fluid, and is contained within the housing volume,
wherein the bag material comprises a Modulus of Elasticity of at least 0.1 GPa and at most 5 GPa,
wherein the bag material comprises a plurality of material layers, wherein at least one of said plurality of layers comprises an insulation layer,
wherein the method comprises:
expanding the bag for reducing the housing volume and for thereby compensating a pressure drop in the housing pressure of the air.

13. The method according to claim 12, wherein the pressure drop in the housing pressure of the air is caused by a temperature drop of the air.

14. A method of equipping a lighting device with a bag made of a bag material,
wherein the lighting device comprises a housing having a housing volume filled with air having a housing pressure,
wherein the housing comprises a light source and a light exit window for outputting light of the light source to the exterior,
wherein the housing further comprises an aperture and a panel for closing said aperture,
wherein the bag is gastightly sealed and is filled with a bag fluid,
wherein the method comprises:
opening said panel for opening said aperture;
equipping the lighting device with said bag for containing the bag within the housing volume;
closing said panel for closing said aperture.

15. The method according to claim 14, wherein the bag is connected to said panel.
